(19) United States
(12) Patent Application Publication
(10) Pub. No.: US 2025/0301772 A1
(43) Pub. Date: Sep. 25, 2025

(54) SEMICONDUCTOR DEVICE AND SEMICONDUCTOR SUBSTRATE INCLUDING SEMICONDUCTOR DEVICE

(71) Applicant: Kioxia Corporation, Tokyo (JP)

(72) Inventors: Tomohiko ITO, Kawasaki Kanagawa (JP); Gaku TAKEMURA, Yokohama Kanagawa (JP); Arata INOUE, Chigasaki Kanagawa (JP); Eiji KUME, Odawara Kanagawa (JP)

(21) Appl. No.: 19/070,349

(22) Filed: Mar. 4, 2025

(30) Foreign Application Priority Data
Mar. 19, 2024 (JP) 2024-044188

(51) Int. Cl. H10D 84/00; H01L 25/18; H10B 80/00; H10D 1/20; H10D 80/30

(52) U.S. Cl. CPC H10D 84/201; H01L 25/18; H10B 80/00; H10D 1/20; H10D 80/30

(57) ABSTRACT

A semiconductor device includes a first inductor including a first coil wiring located on a first plane, a second coil wiring of which at least a part is located on the first plane, and a drive circuit that supplies a common signal to the first coil wiring and the second coil wiring. A first region surrounded by the first coil wiring and a second region surrounded by the second coil wiring overlap each other in a direction that is perpendicular to the first plane.

### CROSS-REFERENCE TO RELATED APPLICATION(S)

This application is based upon and claims the benefit of priority from Japanese Patent Application No. 2024-044188, filed Mar. 19, 2024, the entire contents of which are incorporated herein by reference.

### FIELD

Embodiments described herein relate generally to a semiconductor device and a semiconductor substrate including the semiconductor device.

### BACKGROUND

There are semiconductor devices including inductors for purpose of contactless wireless communication by magnetic coupling. In such semiconductor devices, contactless communication is possible and signal wirings between transmitters and receivers that are needed in wired communication devices can be omitted. Thus, it is possible to reduce transmission losses in the signal wirings.

### BRIEF DESCRIPTION OF THE DRAWINGS

FIG. 1A is a perspective view illustrating contactless wireless communication by magnetic coupling.

FIG. 1B is a diagram illustrating input signals at both ends of a transmission inductor.

FIG. 1C is a diagram illustrating a temporal change in a current flowing in the transmission inductor.

FIG. 2A is a top view illustrating an inductor of a semiconductor device according to an embodiment of the present disclosure.

FIG. 2B is a circuit diagram illustrating a drive unit of the semiconductor device.

FIG. 2C is a perspective view illustrating the inductor of the semiconductor device.

FIG. 2D is a perspective view illustrating the inductor of the semiconductor device.

FIG. 3 is a circuit diagram illustrating a drive unit of the semiconductor device according to one embodiment.

FIG. 4 is a circuit diagram illustrating the drive unit of the semiconductor device according to one embodiment.

FIG. 5 is a sectional view illustrating the semiconductor device according to one embodiment.

FIG. 6 is a sectional view illustrating the semiconductor device according to one embodiment.

FIG. 7 is a top view illustrating a configuration of the semiconductor device according to one embodiment.

FIGS. 8-11 are enlarged top views illustrating the semiconductor substrate according to different embodiments.

### DETAILED DESCRIPTION

Embodiments provide a semiconductor device including an inductor for improving contactless wireless communication that employs magnetic coupling.

In general, according to one embodiment, a semiconductor device includes: a first inductor including a first coil wiring located on a first plane, a second coil wiring of which at least a part is located on the first plane, and a drive circuit that supplies a common signal to the first coil wiring and the second coil wiring. A first region surrounded by the first coil wiring and a second region surrounded by the second coil wiring overlap each other in a direction that is perpendicular to the first plane.

Hereinafter, a semiconductor device and a semiconductor substrate according to the embodiment will be described specifically with reference to the drawings. In the following description, elements that have substantially the same functions and configurations are denoted by the same reference numerals or reference numerals with alphabet letters appended after the same reference numerals, and thus only necessary cases will be described repeatedly. In each of the following embodiments, a device or a method for embodying the technical idea of the embodiment will be described. The embodiments can be modified in various forms within the scope of the present disclosure without departing from the gist of the present disclosure. The embodiments and modifications of the embodiments are included in the equivalent scope of the disclosures described in the claims.

In the drawings, to further clarify description, widths, thicknesses, shapes, and the like of units may be schematically indicated compared to the actual ones, but these are merely example and do not limit the scope of the present disclosure. In the present specification and in the drawings, elements that have functions similar to those described in the described drawings may be given the same reference numerals, and repeated description will be omitted.

In the present specification, expressions such as “α includes A, B, or C” do not exclude cases where a includes a plurality of combinations of A to C unless explicitly mentioned otherwise. Further, these expressions do not exclude cases where α includes other elements.

The following embodiments can be combined with each other as long as technical contradictions are not caused by the embodiments.

### <Contactless Wireless Communication by Magnetic Coupling>

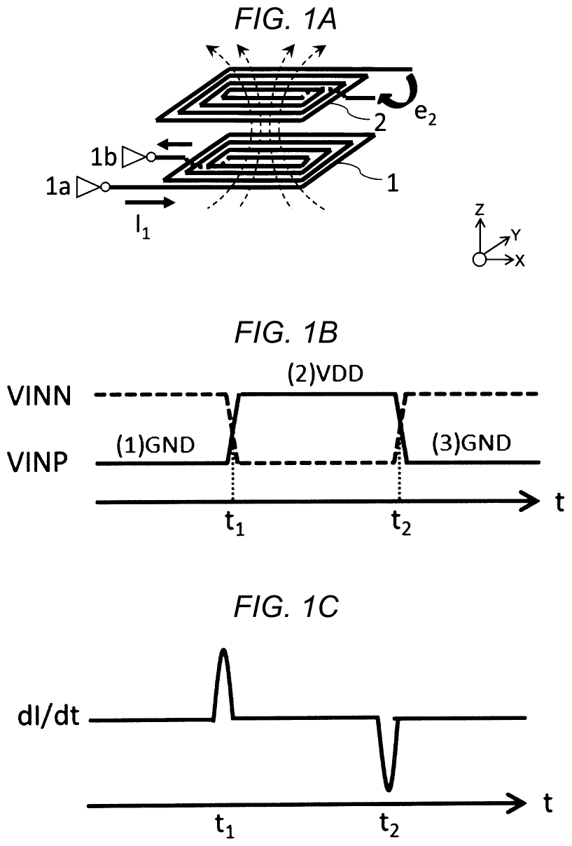

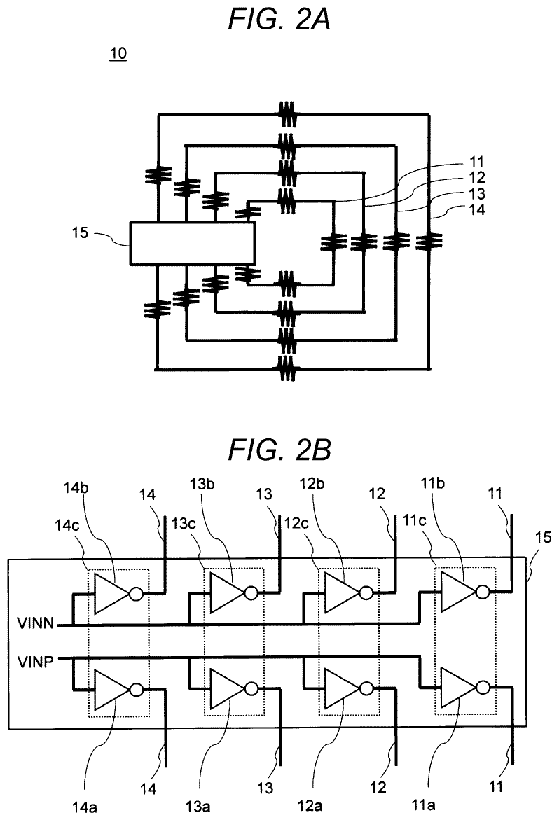

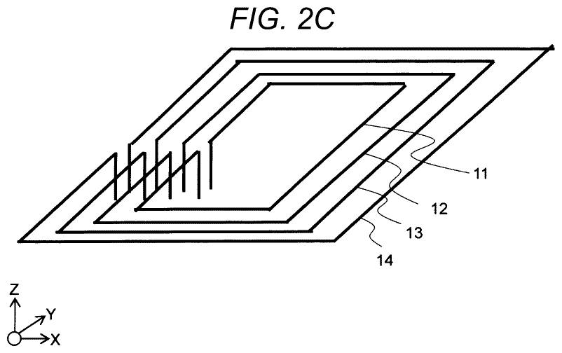

Contactless wireless communication by magnetic coupling will be described with reference to FIGS. 1A to 1C. FIG. 1A is a perspective view illustrating the contactless wireless communication by magnetic coupling. FIG. 1B is a diagram illustrating input signals at both ends of a transmission inductor. FIG. 1C is a diagram illustrating a temporal change in a current flowing in the transmission inductor.

As illustrated in FIG. 1A, when a current flows in a transmission inductor 1, a signal is delivered to a reception inductor 2 paired by mutual induction via a generated magnetic flux. The mutual induction is a phenomenon in which, in two magnetically connected inductors, a change in a current of one inductor leads to generation of an electromotive force in the other inductor. An induced electromotive force e₂ generated in the reception inductor 2 is expressed by the following formula [1].

$${e}_{2} = - M \frac{{dl}_{1}}{dt} \qquad [ 1 ]$$

Here, I₁ indicates a current flowing in the transmission inductor 1 and M indicates mutual inductance. From this formula, it can be understood that magnitude of e₂ increases as a temporal change dI₁/dt of the current I₁ flowing in the transmission inductor 1 becomes steeper.

As illustrated in FIG. 1B, for example, a first inverter circuit 1a is connected at one end of the transmission inductor 1 and a second inverter circuit 1b is connected at the other end of the transmission inductor 1, and input signals at the ends are referred to as VINP and VINN, respectively. Here, VINP is a non-return to zero (NRZ) signal that is 0 (GND) at the time (1) of t<t1, 1 (VDD) at the time (2) of t1<t<t2, and 0 (GND) at the time (3) of t2<t. VINN is an inverted signal of VINP. At the time (1), one end of the transmission inductor 1 connected to the first inverter circuit 1a becomes VDD and the other end of the transmission inductor 1 connected to the second inverter circuit 1b becomes GND, and thus a constant current I₁ that does not vary over time flows in the direction of the illustrated arrow. At time t1, the logic of VINP (VINN) is switched and the direction of the current in the transmission inductor 1 is about to be reversed, which causes an abrupt change in current. When the signal enters the state of (2) after time t1, the one end of the transmission inductor 1 connected to the first inverter circuit 1a becomes GND and the other end of the transmission inductor 1 connected to the second inverter circuit 1b becomes VDD, which causes a constant current −I₁ that does not vary over time in the reverse direction to the state of (1) to flow in the transmission inductor 1. At time t2, the current of the transmission inductor 1 varies abruptly. At this time, since the current of the transmission inductor 1 is about to change from the state of (2) to the state of (1), a temporal change of the current is opposite to that at time t1. As illustrated in FIG. 1C, the abrupt change in the current of the transmission inductor 1 results in a pulse shape only at times t1 and t2, at which the NRZ signal transitions, and is 0 at other times. The directions of the changes in the current at t1 and t2 are opposite to each other.

On the other hand, magnitude of mutual inductance M is expressed in the following formula.

$$M = k \sqrt{{L}_{T} {L}_{R}} \qquad [ 2 ]$$

Here, L_{T} and L_{R} are inductances of the transmission inductor 1 and the reception inductor 2, respectively. In addition, k is a coupling coefficient. k is a function of a distance between two inductors and k decreases as the distance increases.

For example, if shapes (sizes) of two inductors are invariable, the inductances L_{T} and L_{R} become constant. At this time, when the distance between the inductors increases, k decreases and the induced electromotive force e₂ decreases. Thus, normal reception may be difficult. Accordingly, in order to increase a communication distance, it is necessary to increase an instantaneous value of a current flowing in the transmission inductor 1.

A current flowing in the inductor at time t1 or t2 is determined by path resistance and magnitude of a power voltage VDD. The path resistance is a sum of (i) ON-resistance of a transistor enabled by an inverter circuit and (ii) wiring parasitic resistance of the transmission inductor 1. When the path resistance is decreased, the current flowing in the inductor can be increased. When a gate width of a transistor in the inverter circuit is enlarged, the ON-resistance (i) is decreased, and thus the path resistance can be decreased. On the other hand, when a size or a wiring width, a wiring layer, and the number of turns of the inductor are constant, a resistant value of the wiring parasitic resistance (ii) does not vary. Therefore, when ON-resistance (i) becomes sufficiently small in the path resistance, a current value to flow is determined by only the wiring parasitic resistance of the inductor of the wiring parasitic resistance (ii). That is, a maximum distance between inductors capable of performing contactless wireless communication depends on wiring parasitic resistance of the transmission inductor 1.

### First Embodiment

### [Configuration of Inductor]

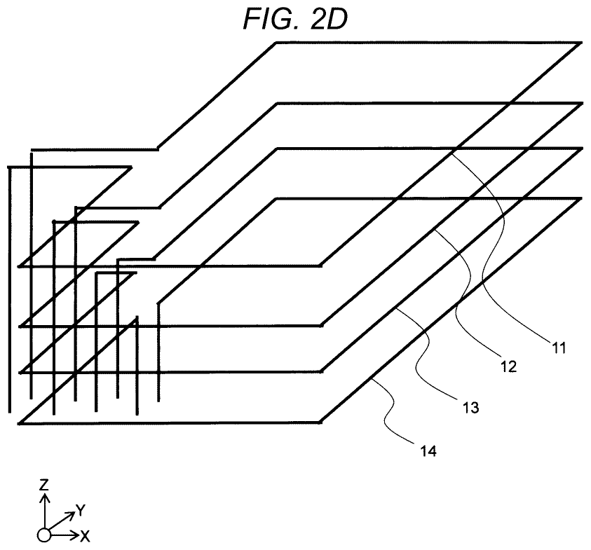

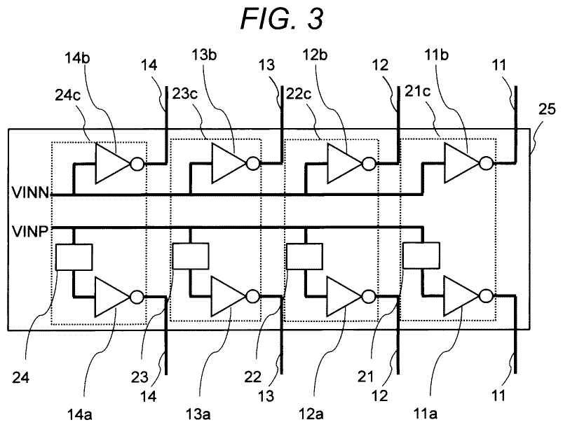

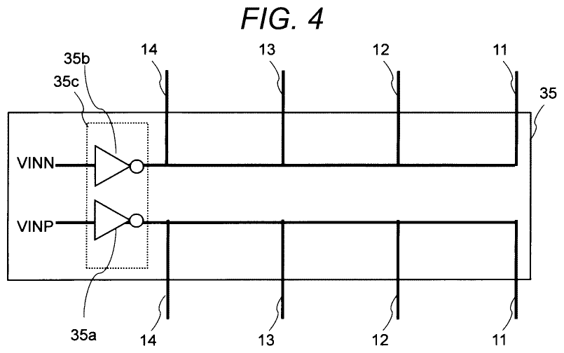

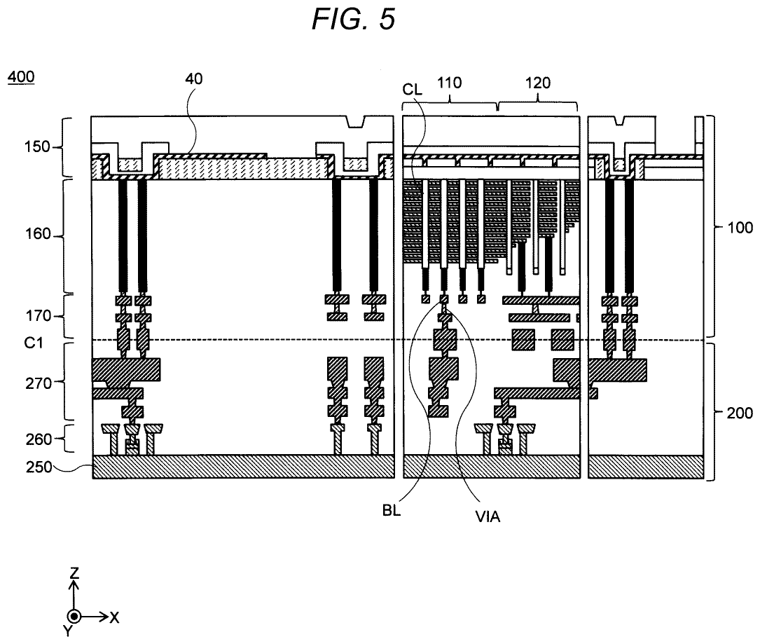

A configuration example of an inductor of a semiconductor device according to the first embodiment will be described with reference to FIGS. 2A to 2C. FIG. 2A is a top view illustrating the inductor of the semiconductor device according to the first embodiment. FIG. 2B is a circuit diagram illustrating a drive unit of the semiconductor device according to the first embodiment. FIG. 2C is a perspective view illustrating the inductor of the semiconductor device according to the first embodiment.

As illustrated in FIGS. 2A and 2B, the inductor 10 includes a first coil wiring 11, a second coil wiring 12, a third coil wiring 13, a fourth coil wiring 14, and a drive unit 15. The first coil wiring 11, the second coil wiring 12, the third coil wiring 13, and the fourth coil wiring 14 are referred to as the coil wirings when they are not distinguished from each other. The first coil wiring 11, the second coil wiring 12, the third coil wiring 13, and the fourth coil wiring 14 are single independent wirings and are electrically separated from each other.

The first coil wiring 11, the second coil wiring 12, the third coil wiring 13, and the fourth coil wiring 14 extend on an XY plane including the X direction and the Y direction perpendicular to the X direction. Both ends that are not connected to each other in each of the first coil wiring 11, the second coil wiring 12, the third coil wiring 13, and the fourth coil wiring 14 are disposed to face each other. The first coil wiring 11, the second coil wiring 12, the third coil wiring 13, and the fourth coil wiring 14 are each disposed in a one-turn square loop shape with a space (a gap between both the facing ends). The first coil wiring 11, the second coil wiring 12, the third coil wiring 13, and the fourth coil wiring 14 each have different lengths. The second coil wiring 12 is longer than the first coil wiring 11, the third coil wiring 13 is longer than the second coil wiring 12, and the fourth coil wiring 14 is longer than the third coil wiring 13. As illustrated in FIG. 2C, the first coil wiring 11, the second coil wiring 12, the third coil wiring 13, and the fourth coil wiring 14 are disposed in the same layer (same plane) in the Z direction perpendicular to the XY plane including the X and Y directions.

However, an embodiment is not limited thereto, the number, shapes, and lengths of coil wirings in the inductor 10 are not particularly limited to the ones described above. The shapes of the coil wirings in the inductor 10 may be, for example, rectangular, regular polygonal, or circular.

The layer in the Z direction in which the coil wirings in the inductor 10 are disposed is not particularly limited to one layer. FIG. 2D is a perspective view illustrating the inductor of the semiconductor device according to a modification of the first embodiment. As illustrated in FIG. 2D, the coil wirings in the inductor 10 may be disposed in different layers in the Z direction parallel to the XY plane and may have the same lengths.

A region surrounded by the first coil wiring 11 is a first region, a region surrounded by the second coil wiring 12 is a second region, a region surrounded by the third coil wiring 13 is a third region, and a region surrounded by the fourth coil wiring 14 is a fourth region. The first, second, third, and fourth regions overlap each other when viewed in the Z direction. In the coil wirings illustrated in FIG. 2A, the second region is larger than the first region, the third region is larger than the second region, and the fourth region is larger than the third region. In addition, the second region includes the first region, the third region includes the second region, and the fourth region includes the third region. That is, the first coil wiring 11 is surrounded by the second coil wiring 12, the second coil wiring 12 is surrounded by the third coil wiring 13, and the third coil wiring 13 is surrounded by the fourth coil wiring 14. However, an embodiment is not limited thereto. For example, as illustrated in FIG. 2D, when the coil wirings are disposed in different layers in the Z direction, the positions, shapes, and the lengths of the coil wirings in the X and Y directions may be the same or the regions surrounded by the coil wirings may overlap each other when viewed in the Z direction.

The center of the first region, the center of the second region, the center of the third region, and the center of the fourth region preferably overlap each other when viewed in the Z direction. Here, the center of each region may be, for example, a point at which the diagonal lines of the regions intersect each other.

When viewed in the Z direction, one end of the first coil wiring 11, one end of the second coil wiring 12, one end of the third coil wiring 13, and one end of the fourth coil wiring 14 are preferably disposed along the same line, and the other end of the first coil wiring 11, the other end of the second coil wiring 12, the other end of the third coil wiring 13, and the other end of the fourth coil wiring 14 are preferably disposed along the same line. The space (defined as the gap between the facing ends) of the first coil wiring 11, the space of the second coil wiring 12, the space of the third coil wiring 13 and the space of the fourth coil wiring 14 preferably have the same length. The centers of the space of the first coil wiring 11, the space of the second coil wiring 12, the space of the third coil wiring 13 and the space of the fourth coil wiring 14 are preferably along the same line including the center of the first region. Here, one end of each coil wiring may be an end located in the same direction with respect to the space of the coil wiring (located at the same position in the Y direction in FIGS. 2A to 2D). The other end of each coil wiring may be an end located opposite to the one end of each coil wiring. However, an embodiment is not limited thereto. For example, when the coil wirings are disposed at different layers in the Z direction, as in the modification of the first embodiment, one end, the other end, and the space of each coil wiring may overlap when viewed in the Z direction.

The first coil wiring 11, the second coil wiring 12, the third coil wiring 13, and the fourth coil wiring 14 are connected to the drive unit 15 that supplies the same signal to each coil wiring. The drive unit 15 includes a first driver 11c that supplies a signal to the first coil wiring 11, a second driver 12c that supplies a signal to the second coil wiring 12, a third driver 13c that supplies a signal to the third coil wiring 13, and a fourth driver 14c that supplies a signal to the fourth coil wiring 14 (here, the first driver 11c, the second driver 12c, the third driver 13c, and the fourth driver 14c are referred to as the drivers when the first driver 11c, the second driver 12c, the third driver 13c, and the fourth driver 14c are not distinguished from each other). The first driver 11c includes a first inverter circuit 11a connected to one end of the first coil wiring 11 and a second inverter circuit 11b connected to the other end of the first coil wiring 11. The second driver 12c includes a first inverter circuit 12a connected to one end of the second coil wiring 12 and a second inverter circuit 12b connected to the other end of the second coil wiring 12. The third driver 13c includes a first inverter circuit 13a connected to one end of the third coil wiring 13 and a second inverter circuit 13b connected to the other end of the third coil wiring 13. The fourth driver 14c includes a first inverter circuit 14a connected to one end of the fourth coil wiring 14 and a second inverter circuit 14b connected to the other end of the fourth coil wiring 14.

The same input signal VINP is input to each of the first inverter circuit 11a of the first driver 11c, the first inverter circuit 12a of the second driver 12c, the first inverter circuit 13a of the third driver 13c, and the first inverter circuit 14a of the fourth driver 14c. The same input signal VINN is input to each of the second inverter circuit 11b of the first driver 11c, the second inverter circuit 12b of the second driver 12c, the second inverter circuit 13b of the third driver 13c, and the second inverter circuit 14b of the fourth driver 14c. That is, the same signal is input for the same time period and in the same direction, to each of the first driver 11c, the second driver 12c, the third driver 13c, and the fourth driver 14c.

In the inductor 10 according to the first embodiment, wiring parasitic resistance in each driver is small since the length of the coil wiring driven by each driver is shorter than the length of the entire inductor 10. The wiring parasitic resistance of the entire inductor 10 can be divided into the plurality of coil wirings, and thus an instantaneous value of a current flowing in the inductor 10 can increase. Therefore, the same signal is input for the same time period in the same direction to all the drivers, and thus the instantaneous value of the current flowing in the inductor 10 can increase and the induced electromotive force e₂ generated in the reception inductor can become larger. As a result, it is possible to increase a communication distance more than an inductor of the related art (for example, transmission inductor 1) that has the same size and improve contactless wireless communication. By inputting the same signal for the same time period in the same direction to each of the plurality of coil wirings, a potential difference between both ends of parasitic capacitance between the plurality of coils decreases. As a result, the instantaneous value of the current flowing in the inductor 10 can further increase.

### Second Embodiment

### [Configuration of Inductor]

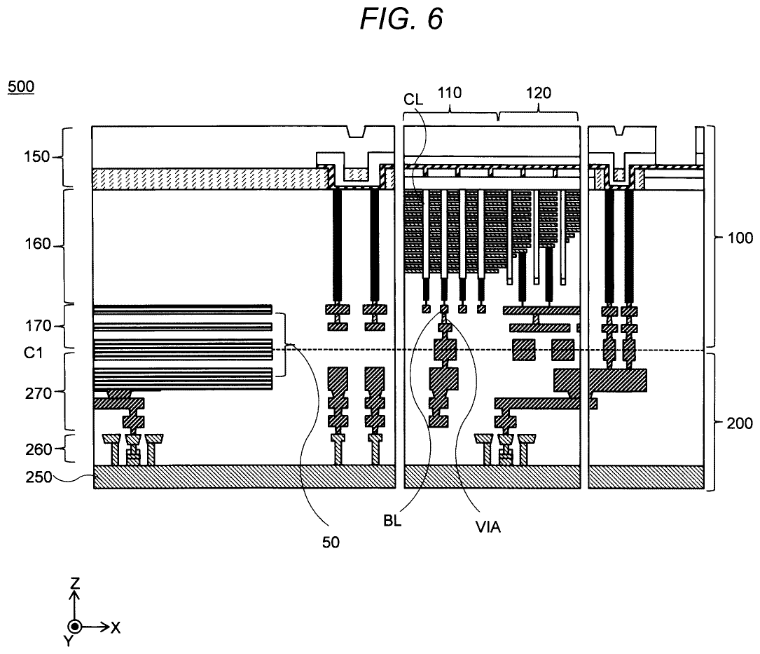

A configuration of an inductor of a semiconductor device according to the second embodiment will be described with reference to FIG. 3. FIG. 3 is a circuit diagram illustrating a drive unit of the semiconductor device according to the second embodiment. The configuration of the inductor according to the second embodiment is the same as the configuration of the inductor 10 according to the first embodiment except that each driver is connected to a timing adjustment circuit. The same description as that of the first embodiment will be omitted. Here, differences from the first embodiment will be described.

As illustrated in FIG. 3, the inductor includes the first coil wiring 11, the second coil wiring 12, the third coil wiring 13, the fourth coil wiring 14, and the drive unit 15. The first coil wiring 11, the second coil wiring 12, the third coil wiring 13, and the fourth coil wiring 14 are connected to the drive unit 25 that supplies the same signal to each coil wiring. Since the structure of the coil wiring is the same as that of the first embodiment, description thereof will be omitted.

The drive unit 25 includes a first driver 21c that supplies a signal to the first coil wiring 11, a second driver 22c that supplies a signal to the second coil wiring 12, a third driver 23c that supplies a signal to the third coil wiring 13, and a fourth driver 24c that supplies a signal to the fourth coil wiring 14 (which are referred to as drivers as in the first embodiment when the first driver 21c, the second driver 22c, the third driver 23c, and the fourth driver 24c are not distinguished from each other).

The first driver 21c includes a first timing adjustment circuit 21, the second driver 22c includes a second timing adjustment circuit 22, the third driver 23c includes a third timing adjustment circuit 23, and the fourth driver 24c includes a fourth timing adjustment circuit 24. The first inverter circuit 11a connected to one end of the first coil wiring 11 is connected to the first timing adjustment circuit 21. The first inverter circuit 12a connected to one end of the second coil wiring 12 is connected to the second timing adjustment circuit 22. The first inverter circuit 13a connected to one end of the third coil wiring 13 is connected to the third timing adjustment circuit 23. The first inverter circuit 14a connected to one end of the fourth coil wiring 14 is connected to the fourth timing adjustment circuit 24.

The same input signal VINP is input to each of the first inverter circuit 11a of the first driver 21c, the first inverter circuit 12a of the second driver 22c, the first inverter circuit 13a of the third driver 23c, and the first inverter circuit 14a of the fourth driver 24c. The same input signal VINN is input to each of the second inverter circuit 11b of the first driver 21c, the second inverter circuit 12b of the second driver 22c, the second inverter circuit 13b of the third driver 23c, and the second inverter circuit 14b of the fourth driver 24c. That is, the same signal is input for the same time period in the same direction to each of the first driver 21c, the second driver 22c, the third driver 23c, and the fourth driver 24c.

For example, when an input timing of a signal to the first driver 21c is earlier than an input timing of a signal to the second driver 22c due to a layout or the like, the input timing of the signal to the first driver 21c may be delayed by the first timing adjustment circuit 21. The adjustment may be performed so that the input timing of the signal to the first driver 21c matches the input timing of the signal to the second driver 22c.

On the other hand, for example, when the lengths of the first coil wiring 11, the second coil wiring 12, the third coil wiring 13, and the fourth coil wiring 14 are different from each other, timings of times t1 and t2 at which a pulse are generated in each coil wiring may deviate even if each driver inputs the same signal for the same time period in the same direction. Accordingly, the first timing adjustment circuit 21, the second timing adjustment circuit 22, the third timing adjustment circuit 23, and the fourth timing adjustment circuit 24 may adjust a timing at which each driver inputs the signal (here, the first timing adjustment circuit 21, the second timing adjustment circuit 22, the third timing adjustment circuit 23, and the fourth timing adjustment circuit 24 are referred to as the timing adjustment circuits when the first timing adjustment circuit 21, the second timing adjustment circuit 22, the third timing adjustment circuit 23, and the fourth timing adjustment circuit 24 are not distinguished from each other).

For example, when the second coil wiring 12 is longer than the first coil wiring 11, the second timing adjustment circuit 22 may advance an input timing of the signal than the first timing adjustment circuit 21. When the third coil wiring 13 is longer than the second coil wiring 12, the third timing adjustment circuit 23 may advance an input timing of the signal than the second timing adjustment circuit 22. When the fourth coil wiring 14 is longer than the third coil wiring 13, the fourth timing adjustment circuit 24 may advance an input timing of the signal than the third timing adjustment circuit 23. The adjustment may be performed so that positions of times t1 and t2 at which a pulse is generated in each coil wiring match each other at a midpoint of one end and the other end of each coil wiring (an opposite side of a space across the center of a region surrounded by each coil wiring).

In the inductor according to the embodiment, each timing adjustment circuit can adjust a timing of a signal input by each driver to adjust the positions of times t1 and t2 at which a pulse is generated in each of a plurality of coil wirings of which lengths are different from each other, an instantaneous value of a current flowing per unit time in the inductor can further increase, and thus the larger induced electromotive force e₂ can be generated in the reception inductor. As a result, it is possible to further increase a communication distance more than an inductor (for example, the transmission inductor 1) of the related art that has the same size and improve contactless wireless communication.

### Third Embodiment

### [Configuration of Inductor]

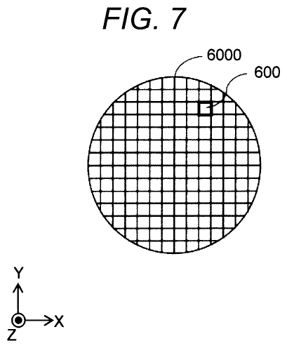

A configuration of an inductor of a semiconductor device according to the third embodiment will be described with reference to FIG. 4. FIG. 4 is a circuit diagram illustrating a drive unit of the semiconductor device according to the third embodiment. The configuration of the inductor according to the third embodiment is the same as the configuration of the inductor 10 according to the first embodiment except that each coil wiring is connected to one driver. The same description as that of the first embodiment will be omitted. Here, differences from the first embodiment will be described.

As illustrated in FIG. 4, the inductor includes the first coil wiring 11, the second coil wiring 12, the third coil wiring 13, the fourth coil wiring 14, and a drive unit 35. The first coil wiring 11, the second coil wiring 12, the third coil wiring 13, and the fourth coil wiring 14 are connected to the drive unit 35 that supplies the same signal to each coil wiring. Since the structure of the coil wiring is the same as that of the first embodiment, description thereof will be omitted.

The drive unit 35 includes a driver 35c that supplies signals to the first coil wiring 11, the second coil wiring 12, the third coil wiring 13, and the fourth coil wiring 14. The driver 35c includes a first inverter circuit 35a connected in parallel to one end of each of the first coil wiring 11, the second coil wiring 12, the third coil wiring 13, and the fourth coil wiring 14, and a second inverter circuit 35b connected in parallel to the other end of each of the first coil wiring 11, the second coil wiring 12, the third coil wiring 13, and the fourth coil wiring 14.

The first inverter circuit 35a of the driver 35c inputs the same input signal VINP to one end of each of the first coil wiring 11, the second coil wiring 12, the third coil wiring 13, and the fourth coil wiring 14. The second inverter circuit 35b of the driver 35c inputs the same input signal VINN to the other end of each of the first coil wiring 11, the second coil wiring 12, the third coil wiring 13, and the fourth coil wiring 14. That is, the driver 35c inputs the same signal for the same time period in the same direction to each coil wiring.

In the inductor 30 according to the third embodiment, the plurality of coil wirings are connected in parallel to one driver, and wiring parasitic resistance of the inductor 30 can be divided, and thus an instantaneous value of a current flowing in the inductor 30 can increase. Therefore, in the inductor 30, the same signal is input for the same time period in the same direction to each of the plurality of coil wirings, and thus the instantaneous value of the current flowing per unit time in the inductor 30 can increase and the larger induced electromotive force e₂ can be generated in the reception inductor. As a result, it is possible to increase a communication distance more than an inductor (for example, the transmission inductor 1) of the related art that has the same size and improve contactless wireless communication.

### Fourth Embodiment

### [Configuration of Semiconductor Device]

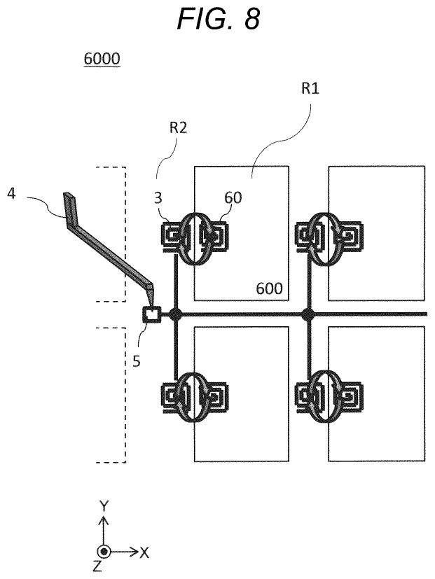

A configuration of a semiconductor device 400 according to the fourth embodiment will be described with reference to FIG. 5. FIG. 5 is a sectional view illustrating a basic configuration of the semiconductor device 400. As illustrated in FIG. 5, the semiconductor device 400 is a bonding substrate and includes a memory cell array chip 100 and a control circuit (CMOS circuit) chip 200. The memory cell array chip 100 and the control circuit chip 200 are connected on a connection surface C1.

### [Structure of Memory Cell Array Chip]

As illustrated in FIG. 5, the memory cell array chip 100 includes a semiconductor element layer that has a source line side wiring layer 150, a plurality of electrode layers 160, and a memory side wiring layer 170. The plurality of electrode layers 160 includes a memory cell array region 110 and a contact region 120. The plurality of electrode layers 160 are alternately stacked with a plurality of insulating layers (not shown). Semiconductor pillars CL penetrates through the plurality of electrode layers 160 to be disposed in a stacking direction. The semiconductor pillars CL are combined with the plurality of electrode layers 160 with the insulating layers interposed therebetween to function as a plurality of transistors including memory cells. That is, in the memory cell array region 110, a plurality of transistors including the memory cells are disposed 3-dimensionally. The semiconductor pillars CL are electrically connected to the memory side wiring layer 170 including bit lines BL at one end (the control circuit chip 200 side) and are electrically connected to the source line side wiring layer 150 including source lines at the other end (the opposite side to the control circuit chip 200). A connection terminal for connection with the control circuit chip 200 is disposed on a connection surface C1 of the memory side wiring layer 170.

The contact region 120 is disposed along with the memory cell array region 110. In the contact region 120, each of the plurality of electrode layers 160 has a stepped terminal portion. Each terminal portion is connected to a wiring in the vertical direction via a contact hole opened to an insulating film. The wirings in the vertical direction are electrically connected to the memory side wiring layer 170 and are connected to the control circuit chip 200 via the connection terminals.

### [Structure of Control Circuit Chip]

As illustrated in FIG. 5, the control circuit chip 200 includes a semiconductor element layer including a substrate 250, a plurality of transistors 260 in a control circuit, and a circuit side wiring layer 270. The plurality of transistors 260 are formed in the substrate 250 and are electrically connected to the circuit side wiring layer 270 on an opposite side to the substrate 250. A connection terminal for connection to the memory cell array chip 100 is disposed on the connection surface C1 of the circuit side wiring layer 270. The substrate 250 may be a semiconductor wafer such as a silicon substrate.

An inductor 40 according to the fourth embodiment corresponds to the first coil wiring 11, the second coil wiring 12, the third coil wiring 13, and the fourth coil wiring 14 described in the first to third embodiments. The inductor 40 according to the fourth embodiment may be disposed in the source line side wiring layer 150. Here, the inductor 40 corresponds to a rear surface wiring of the memory cell array chip 100. As illustrated in FIG. 2C, the inductor 40 may be disposed in the same layer in the Z direction. Some of the plurality of transistors 260 according to the fourth embodiment correspond to the drive unit 15.

The inductor 40 according to the fourth embodiment can divide wiring parasitic resistance of the inductor 40, and thus an instantaneous value of a current flowing in the inductor 40 can increase. In the inductor 40, the same signal is input for the same time period in the same direction to each of the plurality of coil wirings, and thus an instantaneous value of a current flowing per unit time in the inductor 40 can increase and the larger induced electromotive force e₂ can be generated in the reception inductor. As a result, it is possible to increase a communication distance of the semiconductor device 400 according to the fourth embodiment and improve contactless wireless communication.

### Fifth Embodiment

### [Configuration of Semiconductor Device]

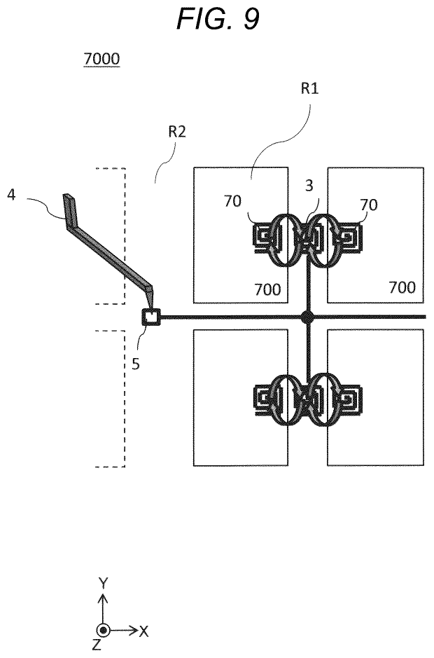

A configuration of a semiconductor device 500 according to the fifth embodiment will be described with reference to FIG. 6. FIG. 6 is a sectional view illustrating a basic configuration of the semiconductor device 500. The configuration of the semiconductor device 500 according to the fifth embodiment is the same as the configuration of the semiconductor device 400 according to the fourth embodiment except for the position of the inductor. The same description as that of the fourth embodiment will be omitted. Here, differences from the fourth embodiment will be described.

As illustrated in FIG. 6, the semiconductor device 500 is a bonding substrate and includes the memory cell array chip 100 and a control circuit chip 200. The memory cell array chip 100 and the control circuit chip 200 are connected on a connection surface C1. Since structures of the memory cell array chip 100 and the control circuit chip 200 are the same as those of the fourth embodiment, description thereof will be omitted.

An inductor 50 according to the fifth embodiment has the configuration described in the first to third embodiments and may be disposed in the memory side wiring layer 170 and the circuit side wiring layer 270. Here, at least one layer of the inductor 50 may be disposed on the connection surface C1 of the memory side wiring layer 170 or the circuit side wiring layer 270. Another layer of the inductor 50 may be disposed in a layer other than the connection surface C1 of the memory side wiring layer 170 or the circuit side wiring layer 270. As illustrated in FIG. 2D, the inductor 50 may be disposed in different layers in the Z direction.

The inductor 50 according to the fifth embodiment can divide wiring parasitic resistance of the inductor 50, and thus an instantaneous value of a current flowing in the inductor 50 can increase. In the inductor 50, the same signal is input for the same time period in the same direction to each of the plurality of coil wirings, and thus an instantaneous value of a current flowing per unit time in the inductor 50 can increase and the larger induced electromotive force e₂ can be generated in the reception inductor. As a result, it is possible to increase a communication distance of the semiconductor device 500 according to the fifth embodiment and improve contactless wireless communication.

### Sixth Embodiment

### [Configuration of Semiconductor Substrate]

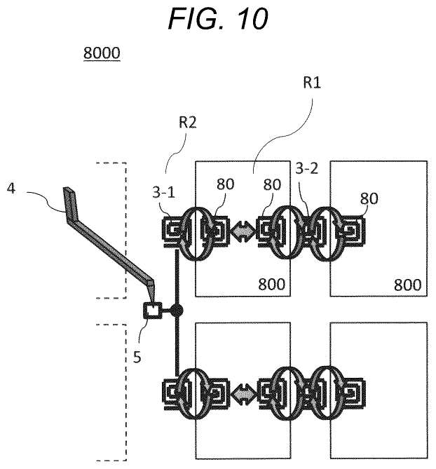

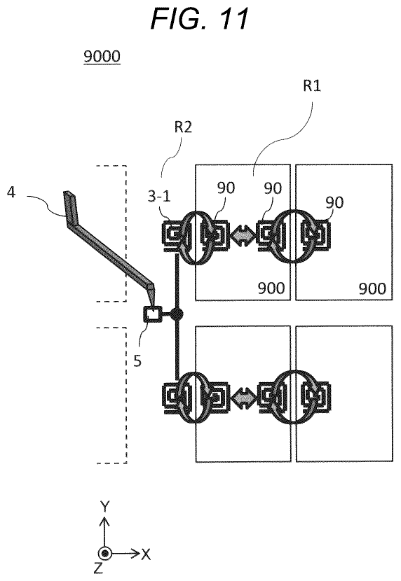

A configuration of a semiconductor substrate 6000 according to the sixth embodiment will be described with reference to FIGS. 7 and 8. FIG. 7 is a top view illustrating a basic configuration of the semiconductor substrate. FIG. 8 is an enlarged top view illustrating the semiconductor substrate. As illustrated in FIGS. 7 and 8, the semiconductor substrate 6000 includes a plurality of effective element regions R1 for manufacturing the plurality of semiconductor devices 600. The effective element regions R1 are disposed in a matrix form in the semiconductor substrate 6000. The semiconductor substrate 6000 includes ineffective element region R2 cut in segmentation of the semiconductor device 600 in the periphery of each effective element region R1.

An inductor 60 is disposed in each of the plurality of effective element regions R1 of the semiconductor substrate 6000. The inductor 60 according to the sixth embodiment has the configuration described in the first to fifth embodiments. The reception inductor 3 that has a one-to-one correspondence relation with each of the plurality of inductors 60 is disposed in the ineffective element region R2 of the semiconductor substrate 6000. The configuration of the reception inductor 3 is not particularly limited to the one described herein. A transmission and reception inverter circuit such as a drive unit and a power supply unit are added to the reception inductor 3. The configuration of the circuits appended to the reception inductor 3 is not particularly limited to the one described herein.

The inductor 60 disposed in the effective element region R1 and the reception inductor 3 disposed in the ineffective element region R2 are disposed close to be magnetically coupled. The inductor 60 according to the sixth embodiment can generate the larger induced electromotive force e₂ in the reception inductor 3.

Each of the plurality of reception inductors 3 is connected to a common external terminal 5 disposed in the ineffective element region R2. The external terminal 5 is disposed at an end of the semiconductor substrate 6000. The external terminal 5 is used, for example, when a test signal is transmitted to the semiconductor device 600. The test signal is input from a probe 4 of a communication device to each reception inductor 3 via the external terminal 5. The test signal is transmitted by contactless wireless communication between the inductor 60 and the corresponding reception inductor 3 to the inside of all the semiconductor devices 600 connected to the external terminal 5. When a unit supplying power to the reception inductor 3 is necessary, the unit can be shared among the plurality of reception inductors 3 to simplify a power supply unit. A method such as a laser or wireless power feeding can also be applied.

The semiconductor substrate 6000 according to the sixth embodiment transmits the test signal using a contactless communication method inside the semiconductor substrate 6000, and thus the total number of probes 4 necessary for the communication device can be reduced. Therefore, a total load of the communication device is reduced and a price of the communication device can be lowered.

The inductor 60 according to the sixth embodiment can divide wiring parasitic resistance of the inductor 60, and thus an instantaneous value of a current flowing in the inductor 60 can increase. In the inductor 60, the same signal is input for the same time period in the same direction to each of the plurality of coil wirings, and thus an instantaneous value of a current flowing per unit time in the inductor 60 can increase and the larger induced electromotive force e₂ can be generated in the reception inductor 3. Accordingly, it is possible to improve contactless wireless communication in the semiconductor substrate 6000 of the semiconductor device 600 according to the sixth embodiment. Further, since the inductor 60 and the corresponding reception inductor 3 are disposed close, a signal can be transmitted despite a small inductor area and an increase in the area of the semiconductor device 600 can be inhibited.

### Seventh Embodiment

### [Configuration of Semiconductor Substrate]

A configuration of a semiconductor substrate 7000 according to the seventh embodiment will be described with reference to FIG. 9. FIG. 9 is an enlarged top view illustrating the semiconductor substrate. The configuration of the semiconductor substrate 7000 according to the seventh embodiment is the same as the configuration of the semiconductor substrate 6000 according to the sixth embodiment except for the disposition and number of inductors. The same description as that of the sixth embodiment will be omitted. Here, differences from the sixth embodiment will be described.

An inductor 70 is disposed in each of the plurality of effective element regions R1 of the semiconductor substrate 7000. The inductor 70 according to the seventh embodiment has the configuration described in the first to fifth embodiments. The plurality of reception inductors 3 that have a two-to-one correspondence relation with two inductors 70 are disposed in the ineffective element region R2 of the semiconductor substrate 7000. The configuration of the reception inductor 3 is not particularly limited to the one described herein. A transmission and reception inverter circuit such as a drive unit and a power supply unit are added to the reception inductor 3. The configuration of the circuits appended to the reception inductor 3 is not particularly limited to the one described herein.

Each of the inductors 70 disposed in two effective element regions R1 and the reception inductor 3 disposed in the ineffective element region R2 are disposed close to be magnetically coupled. Therefore, two inductors 70 disposed in each effective element region R1 are preferably disposed to interpose the reception inductor 3. The inductor 70 according to the seventh embodiment can generate the large induced electromotive force e₂ in the reception inductor 3.

Each of the plurality of reception inductors 3 is connected to a common external terminal 5 disposed in the ineffective element region R2. The external terminal 5 is disposed at an end of the semiconductor substrate 7000. The external terminal 5 is used, for example, when a test signal is transmitted to the semiconductor device 700. The test signal is input from the probe 4 of a communication device to each reception inductor 3 via the external terminal 5. The test signal is transmitted by contactless wireless communication between the inductor 70 and the corresponding reception inductor 3 to the inside of all the semiconductor devices 700 connected to the external terminal 5.

The semiconductor substrate 7000 according to the seventh embodiment transmits the test signal using a contactless communication method inside the semiconductor substrate 7000, and thus the total number of probes 4 necessary for the communication device can be reduced. Therefore, a total load of the communication device is reduced and a price of the communication device can be lowered.

The inductor 70 according to the seventh embodiment can divide wiring parasitic resistance of the inductor 70, and thus an instantaneous value of a current flowing in the inductor 70 can increase. In the inductor 70, the same signal is input for the same time period in the same direction to each of the plurality of coil wirings, and thus an instantaneous value of a current flowing per unit time in the inductor 70 can increase and the larger induced electromotive force e₂ can be generated in the reception inductor 3. Accordingly, it is possible to improve contactless wireless communication in the semiconductor substrate 7000 of the semiconductor device 700 according to the seventh embodiment. Further, the number of reception inductors 3 corresponding to the inductor 70 can be reduced, and thus an increase in the area of the semiconductor device 700 can be inhibited.

### Eighth Embodiment

### [Configuration of Semiconductor Substrate]

A configuration of a semiconductor substrate 8000 according to the eighth embodiment will be described with reference to FIG. 10. FIG. 10 is an enlarged top view illustrating the semiconductor substrate. A configuration of the semiconductor substrate 8000 according to the eighth embodiment is the same as the configuration of the semiconductor substrate 6000 according to the sixth embodiment except for the disposition and number of inductors. The same description as that of the sixth embodiment will be omitted. Here, differences from the sixth embodiment will be described.

A plurality of inductors 80 are disposed in each of the plurality of effective element regions R1 of the semiconductor substrate 8000. The inductor 80 according to the eighth embodiment has the configuration described in the first to fifth embodiments. The plurality of reception inductors 3-1 that have a one-to-one correspondence relation with each inductor 80 and the plurality of reception inductors 3-2 that have a two-to-one correspondence relation with two inductors 80 are disposed in the ineffective element region R2 of the semiconductor substrate 8000. The configuration of the reception inductors 3-1 and 3-2 is not particularly limited to the one described herein.

The plurality of inductors 80 disposed in one effective element region R1 are disposed close to be magnetically coupled. The inductors 80 disposed in one effective element region R1 according to the eighth embodiment can generate the large induced electromotive force e₂.

The inductor 80 disposed in the effective element region R1 and the reception inductor 3-1 disposed in the ineffective element region R2 are disposed close to be magnetically coupled. The inductors 80 according to the eighth embodiment can generate the large induced electromotive force e₂ in the reception inductor 3.

Each of the inductors 80 disposed in two effective element regions R1 and the reception inductor 3-2 disposed in the ineffective element region R2 are disposed close to be magnetically coupled. Two inductors 80 disposed in each effective element region R1 are preferably disposed to interpose the reception inductor 3-2. The inductors 80 according to the eighth embodiment can generate the large induced electromotive force e₂ in the reception inductor 3-2.

Each of the plurality of reception inductors 3-1 is connected to the common external terminal 5 disposed in the ineffective element region R2. The external terminal 5 is disposed at an end of the semiconductor substrate 8000. The external terminal 5 is used, for example, when a test signal is transmitted to the semiconductor device 800. The test signal is input from the probe 4 of a communication device to each reception inductor 3-1 via the external terminal 5. The test signal is transmitted by contactless wireless communication between the inductor 80 and the corresponding reception inductor 3-1 to the inside of all the semiconductor devices 800 connected to the external terminal 5. The test signal is transmitted by contactless wireless communication between the inductors 80 disposed in the same effective element region R1 and is also transmitted to the inside of the semiconductor device 800 not connected to the external terminal 5 by contactless wireless communication with the inductor 80 in another effective element region R1 including the semiconductor device 800 not connected to the external terminal 5 via the reception inductor 3-2 that has a two-to-one correspondence relation with two inductors 80.

The semiconductor substrate 8000 according to the eighth embodiment transmits the test signal using a contactless communication method inside the semiconductor substrate 8000, and thus the total number of probes 4 necessary for the communication device can be reduced. Therefore, a total load of the communication device is reduced and a price of the communication device can be lowered.

The inductor 80 according to the eighth embodiment can divide wiring parasitic resistance of the inductor 80, and thus an instantaneous value of a current flowing in the inductor 80 can increase. In the inductor 80, the same signal is input for the same time period in the same direction to each of the plurality of coil wirings, and thus an instantaneous value of a current flowing per unit time in the inductor 80 can increase and the larger induced electromotive force e₂ can be generated in the reception inductor 3-1 and the reception inductor 3-2. Accordingly, it is possible to improve contactless wireless communication in the semiconductor substrate 8000 of the semiconductor device 800 according to the eighth embodiment. Further, the number of wirings between the reception inductor 3-1 and the external terminal 5 can be reduced, and thus a communication speed between the semiconductor devices 800 can be improved.

### Ninth Embodiment

### [Configuration of Semiconductor Substrate]

A configuration of a semiconductor substrate 9000 according to the ninth embodiment will be described with reference to FIG. 11. FIG. 11 is an enlarged top view illustrating the semiconductor substrate. The configuration of the semiconductor substrate 9000 according to the ninth embodiment is the same as the configuration of the semiconductor substrate 6000 according to the sixth embodiment except for the disposition and number of inductors. The same description as that of the sixth embodiment will be omitted. Here, differences from the sixth embodiment will be described.

A plurality of inductors 90 is disposed in each of the plurality of effective element regions R1 of the semiconductor substrate 9000. The inductor 90 according to the ninth embodiment has the configuration described in the first to fifth embodiments. The plurality of reception inductors 3-1 that have a one-to-one correspondence relation with each of the inductors 90 are disposed in the ineffective element region R2 of the semiconductor substrate 9000. The configuration of the reception inductor 3-1 is not particularly limited to the one described herein.

The plurality of inductors 90 disposed in one effective element region R1 are disposed close to be magnetically coupled. The inductors 90 disposed in one effective element region R1 according to the ninth embodiment can generate the large induced electromotive force e₂.

The inductors 90 disposed in each of different effective element regions R1 are disposed close to be magnetically coupled. The inductors 90 disposed in different effective element regions R1 according to the ninth embodiment can generate the induced electromotive force e₂.

The inductor 90 disposed in the effective element region R1 and the reception inductor 3-1 disposed in the ineffective element region R2 are disposed close to be magnetically coupled. The inductors 90 according to the ninth embodiment can generate the large induced electromotive force e₂ in the reception inductor 3-1.

Each of the plurality of reception inductors 3-1 is connected to a common external terminal 5 disposed in the ineffective element region R2. The external terminal 5 is disposed at an end of the semiconductor substrate 9000. The external terminal 5 is used, for example, when a test signal is transmitted to the semiconductor device 900. The test signal is input from the probe 4 of a communication device to each reception inductor 3-1 via the external terminal 5. The test signal is transmitted by contactless wireless communication between the inductor 90 and the corresponding reception inductor 3-1 to the inside of all the semiconductor devices 900 connected to the external terminal 5. The test signal is transmitted by contactless wireless communication between the inductors 90 disposed in the same effective element region R1 and is also transmitted to the inside of the semiconductor device 900 not connected to the external terminal 5 by contactless wireless communication between the inductors 90 disposed in different effective element regions R1 including the semiconductor device 900 not connected to the external terminal 5.

The semiconductor substrate 9000 according to the ninth embodiment transmits the test signal using a contactless communication method inside the semiconductor substrate 9000, and thus the total number of probes 4 necessary for the communication device can be reduced. Therefore, a total load of the communication device is reduced and a price of the communication device can be lowered.

The inductor 90 according to the ninth embodiment can divide wiring parasitic resistance of the inductor 90, and thus an instantaneous value of a current flowing in the inductor 90 can increase. In the inductor 90, the same signal is input for the same time period in the same direction to each of the plurality of coil wirings, and thus an instantaneous value of a current flowing per unit time in the inductor 90 can increase and the larger induced electromotive force e₂ can be generated in the reception inductor 3-1. Accordingly, it is possible to improve contactless wireless communication in the semiconductor substrate 9000 of the semiconductor device 900 according to the ninth embodiment. Further, the number of reception inductors 3-2 corresponding to the inductors 90 can be reduced, an increase in the area of the semiconductor device 900 can be inhibited. The number of wirings between the reception inductor 3-1 and the external terminal 5 can be reduced, a communication speed between the semiconductor devices 900 can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first inductor including
a first coil wiring located on a first plane,
a second coil wiring of which at least a part is located on the first plane, and
a drive circuit that supplies a common signal to the first coil wiring and the second coil wiring,
wherein a first region surrounded by the first coil wiring and a second region surrounded by the second coil wiring overlap each other in a direction that is perpendicular to the first plane.

2. The semiconductor device according to claim 1, wherein the drive circuit includes
a first driver supplying the signal to the first coil wiring, and
a second driver supplying the signal to the second coil wiring.

3. The semiconductor device according to claim 2, further comprising:
a first timing adjustment circuit connected to the first driver; and
a second timing adjustment circuit connected to the second driver.

4. The semiconductor device according to claim 1, further comprising:
a first chip including a first semiconductor element layer; and
a second chip bonded to the first chip and including a second semiconductor element layer,
wherein the first coil wiring and the second coil wiring are disposed on a surface of the first chip, that is opposite to a bonding surface of the first and second chips.

5. A semiconductor substrate comprising:
a first semiconductor device which includes a first inductor including a first coil wiring located on a first plane, a second coil wiring of which at least a part is located on the first plane, and a drive circuit that supplies a first common signal to the first coil wiring and the second coil wiring, wherein a first region surrounded by the first coil wiring and a second region surrounded by the second coil wiring overlap each other in a direction that is perpendicular to the first plane; and
a second inductor which is disposed in an ineffective element region surrounding the first semiconductor device and which is magnetically coupled with the first inductor.

6. The semiconductor substrate according to claim 5, further comprising:
a second semiconductor device which includes a third inductor magnetically coupled with the second inductor and including a third coil wiring located on a second plane, a fourth coil wiring of which at least a part is located on the second plane, and a second drive circuit that supplies a second common signal to the third coil wiring and the fourth coil wiring, wherein a third region surrounded by the third coil wiring and a fourth region surrounded by the fourth coil wiring overlap each other when viewed in a direction that is perpendicular to the second plane.

7. The semiconductor substrate according to claim 6, wherein the first plane and the second plane are parts of the same plane.

8. The semiconductor substrate according to claim 5, wherein
the first semiconductor device further includes a fourth inductor magnetically coupled with the first inductor and including a fifth coil wiring located on a third plane, a sixth coil wiring of which at least a part is located on the third plane, and a third drive circuit that supplies a third common signal to the fifth coil wiring and the sixth coil wiring, wherein a fifth region surrounded by the fifth coil wiring and a sixth region surrounded by the sixth coil wiring overlap each other in a direction that is perpendicular to the third plane, and
the semiconductor substrate further includes a second semiconductor device that includes a fifth inductor magnetically coupled with the fourth inductor and including a seventh coil wiring located on a fourth plane, an eighth coil wiring of which at least a part is located on the fourth plane, and a fourth drive circuit that supplies a fourth common signal to the seventh coil wiring and the eighth coil wiring, wherein a seventh region surrounded by the seventh coil wiring and an eighth region surrounded by the eighth coil wiring overlap each other when viewed in a direction that is perpendicular to the fourth plane.

9. The semiconductor substrate according to claim 8, wherein the first plane, the third plane, and the fourth plane are parts of the same plane.

10. The semiconductor substrate according to claim 5, further comprising:
a second semiconductor device; and
a third inductor which is disposed in an ineffective element region that is between the first semiconductor device and the second semiconductor device, wherein
the first semiconductor device further includes a fourth inductor magnetically coupled with the first inductor and the third inductor, and including a fifth coil wiring located on a third plane, a sixth coil wiring of which at least a part is located on the third plane, and a third drive circuit that supplies a third common signal to the fifth coil wiring and the sixth coil wiring, wherein a fifth region surrounded by the fifth coil wiring and a sixth region surrounded by the sixth coil wiring overlap each other in a direction that is perpendicular to the third plane, and
the second semiconductor device includes a fifth inductor magnetically coupled with the third inductor and including a seventh coil wiring located on a fourth plane, an eighth coil wiring of which at least a part is located on the fourth plane, and a fourth drive circuit that supplies a fourth common signal to the seventh coil wiring and the eighth coil wiring, wherein a seventh region surrounded by the seventh coil wiring and an eighth region surrounded by the eighth coil wiring overlap each other in a direction that is perpendicular to the fourth plane.

11. The semiconductor substrate according to claim 10, wherein the first plane, the third plane, and the fourth plane are parts of the same plane.

12. The semiconductor substrate according to claim 5, further comprising an external terminal connected to the second inductor.

13. A semiconductor substrate comprising:
a plurality of semiconductor devices;
dicing regions around and between the semiconductor devices;
a test probe pad mounted in the dicing regions; and
first and second inductors located in the dicing regions and electrically connected to the test probe pad through respective first and second wirings, wherein:
the plurality of semiconductor devices include a first semiconductor device with a third inductor magnetically coupled to the first inductor and a second semiconductor device with a fourth inductor magnetically coupled to the second inductor;
the third inductor includes:
a first coil wiring located on a first plane,
a second coil wiring of which at least a part is located on the first plane, and
a first drive circuit that supplies a first common signal to the first coil wiring and the second coil wiring;
the fourth inductor includes:
a third coil wiring located on a second plane,
a fourth coil wiring of which at least a part is located on the second plane, and
a second drive circuit that supplies a second common signal to the third coil wiring and the fourth coil wiring; and
a first region surrounded by the first coil wiring and a second region surrounded by the second coil wiring overlap each other in a first direction that is perpendicular to the first plane, and a third region surrounded by the third coil wiring and a fourth region surrounded by the fourth coil wiring overlap each other in a second direction that is perpendicular to the second plane.

14. The semiconductor substrate according to claim 13, wherein the first plane and the second plane are parts of the same plane.

15. The semiconductor substrate according to claim 13, wherein the plurality of semiconductor devices include a third semiconductor device with a fifth inductor magnetically coupled to the first inductor and a fourth semiconductor device with a sixth inductor magnetically coupled to the second inductor.

16. The semiconductor substrate according to claim 13, wherein the first semiconductor device further includes a fifth conductor magnetically coupled to the third inductor and the second semiconductor device further includes a sixth conductor magnetically coupled to the fourth inductor.

17. The semiconductor substrate according to claim 16, wherein the plurality of semiconductor devices include a third semiconductor device with a seventh inductor magnetically coupled to the fifth inductor and a fourth semiconductor device with an eighth inductor magnetically coupled to the sixth inductor.

18. The semiconductor substrate according to claim 16, further comprising:
a seventh inductor magnetically coupled to the fifth inductor; and
an eighth inductor magnetically coupled to the sixth inductor,
wherein the plurality of semiconductor devices include a third semiconductor device with a ninth inductor magnetically coupled to the seventh inductor and a fourth semiconductor device with a tenth inductor magnetically coupled to the eighth inductor.

19. The semiconductor substrate according to claim 13, wherein the plurality of semiconductor devices are each a semiconductor memory device that includes a memory chip bonded to a peripheral circuit chip and third and fourth inductors are formed on a first surface of the memory chip that is opposite to a second surface of the memory chip that is bonded to the peripheral circuit chip.

20. The semiconductor substrate according to claim 19, wherein the memory chip has a memory array region surrounded by a contact region and the third and fourth inductors are formed in the contact region.
